(19) United States
(12) Patent Application Publication
(10) Pub. No.: US 2012/0256185 A1
(43) Pub. Date: Oct. 11, 2012

(54) SEMICONDUCTOR DEVICE AND PROCESS FOR PRODUCTION THEREOF, AND DISPLAY DEVICE

(75) Inventor: Yoshinobu Nakamura, Osaka-shi (JP)

(73) Assignee: SHARP KABUSHIKI KAISHA, Osaka-shi, Osaka (JP)

(21) Appl. No.: 13/516,512

(22) PCT Filed: Dec. 14, 2010
(86) PCT No.: PCT/JP2010/072437

§ 371 Date: Jun. 15, 2012

(30) Foreign Application Priority Data
Dec. 21, 2009 (JP) 2009-289821

(51) Int. Cl. H01L 27/088; H01L 21/20; H01L 33/08

(52) U.S. Cl. 257/59; 257/57; 438/487; 257/E27.06; 257/E33.053; 257/E21.09

(57) ABSTRACT

The semiconductor device (100A) of the present invention includes an insulating substrate (11), and a first and a second thin film transistors (10A and 10B) supported by the insulating substrate (11). The first and the second thin film transistors (10A and 10B) have respective channel regions (33a and 33b). The channel region (33a) of the first thin film transistor (10A) is formed in a first crystalline semiconductor layer (30A) having a first average grain diameter. The channel region (33b) of the second thin film transistor (10B) is formed in a second crystalline semiconductor layer (30B) having a second average grain diameter which is smaller than the first average grain diameter. The thickness of the first crystalline semiconductor layer (30A) is larger than the thickness of the second crystalline semiconductor layer (30B).

### TECHNICAL FIELD

The present invention relates to a semiconductor device provided with a thin film transistor (Thin Film Transistor: TFT) and a production method thereof, and a display device.

### BACKGROUND ART

Recently, technique for fabricating a semiconductor layer having a crystalline structure by crystallizing an amorphous semiconductor layer formed on an insulating substrate such as a glass substrate (hereinafter referred to as a crystalline semiconductor layer) is widely used. Since the crystalline semiconductor layer has higher mobility than the amorphous semiconductor layer, a TFT utilizing the crystalline semiconductor layer can be used as not only a TFT for a pixel, but also a TFT for a driving circuit or the like in an active matrix liquid crystal display device and the like. In recent years, a full monolithic liquid crystal display device in which peripheral circuits such as a driving circuit are fabricated on a TFT substrate is being widely spread.

The crystalline semiconductor layer is, for example, a polycrystalline semiconductor layer or a microcrystalline semiconductor layer. Crystallizing methods for forming such a crystalline semiconductor layer include a method in which an amorphous semiconductor layer is once melted and then crystallized, and a method in which the amorphous semiconductor layer is crystallized by solid phase crystallization without being melted (Solid Phase Crystallization: SPC). As a method for forming a microcrystalline semiconductor layer, high-density plasma CVD is know. According to the method, heat treatment is not required.

As solid phase crystallization, there is developed solid phase crystallization in which a metal element (a catalyst element: nickel, palladium, or lead, for example) having a function for promoting the crystallization of an amorphous semiconductor film is added, and then heat treatment is performed, so that a crystalline semiconductor can be obtained by heat treatment at lower temperatures than prior art (e.g. about at 600° C.) for a short period of time (e.g. about for one hour) (see Patent Document No. 1). A crystalline silicon film obtained by the above-mentioned method is referred to as continuous grain crystalline silicon (CG silicon), and is practically used. As for the CG silicon, grain boundaries which have perfectly inconsistent crystal planes are not formed, and large crystal grains are included. The size of crystal grains of CG silicon depends on the production process. An average grain diameter thereof is about 2 μm or more, which is larger than an average grain diameter (typically about 200 nm) of a polycrystalline silicon (Low temperature Poly-Silicon: LPS) fabricated by general laser crystallization (melt crystallization). In addition, the crystal grains of CG silicon have higher crystal orientation, thereby having superior electrical properties (e.g. higher mobility).

In order to crystallize an amorphous semiconductor layer, it is necessary to heat the amorphous semiconductor layer in both methods. The known heating methods include a method utilizing a furnace annealing oven, Rapid Thermal Annealing (RTA), laser annealing, and the like. As for these heating methods, either one of them or the combination of two or more of them is used. Especially, attention is focused on the laser annealing as a method for forming a crystalline semiconductor layer on a substrate made of glass having a lower strain point or plastic because the semiconductor layer can be heated without too much increasing the temperature of the substrate. For example, a beam of pulse laser represented by excimer laser is formed so as to have a predetermined shape, and the beam scan is performed on the semiconductor layer.

Patent Documents No. 2 through No. 4 disclose a method in which laser annealing is performed after a CG silicon layer is formed by solid phase crystallization. Patent Document No. 4 describes a method in which laser annealing is performed twice after a CG silicon layer is formed. The entire contents of Patent Documents No. 1 to No. 4 are incorporated by reference in the present specification.

However, as for a TFT having such a CG silicon layer in a channel region, threshold voltages (hereinafter also referred to as Vth) may vary among a plurality of TFTs. This is because the crystal grains included in the CG silicon layer are relatively large, so that the number of crystal grains included in the channel region is varied between TFTs. For example, if Vth of a pixel TFT (e.g. the size of a channel region is 3 μm×3 μm) in a liquid crystal display device varies, the brightness and colors of the liquid crystal display device may also vary, which causes degradation in display quality.

According to the method described in Patent Document No. 2, laser annealing is performed once after a CG silicon layer is formed, so that the CG silicon layer and a normal polycrystalline silicon layer are formed. A TFT having the CG silicon layer is suitable for a driving circuit, and the polycrystalline silicon layer is used for the pixel TFT. In Patent Document No. 2, the process step of forming the CG silicon layer is referred to as a pre-crystallization, and the CG silicon layer is referred to as a silicon layer with higher degree of crystallinity.

### CITATION LIST

### Patent Literature

Patent Document No. 1: Japanese Laid-Open Patent Publication No. 6-244103
Patent Document No. 2: Japanese Laid-Open Patent Publication No. 10-41231
Patent Document No. 3: Japanese Laid-Open Patent Publication No. 2000-216089
Patent Document No. 4: Japanese Laid-Open Patent Publication No. 2007-115786

### SUMMARY OF INVENTION

### Technical Problem

However, the method described in Patent Document No. 2 involves such problems that the process is complicated, and the production cost is increased. In addition, the method described in Patent Document No. 2 essentially requires the process step of selectively applying a catalyst element only to a region forming the CG silicon layer in the amorphous silicon layer. In order to optimize the irradiation intensity of laser light with which the region for forming the CG silicon layer is irradiated and the irradiation intensity of laser light with which the other region is irradiated, respectively, a patterned upper layer (a silicon dioxide (SiO₂) layer) having a predetermined thickness is formed, and the laser annealing process is performed once. According to this method, the laser annealing process is performed only once, but it is necessary to perform another process step of removing the upper layer.

The present invention has been conducted in view of the above-described problems, and the objective thereof is to provide a semiconductor device including TFTs having crystalline semiconductor layers with crystal grains of mutually different average grain diameters on one and the same substrate, the semiconductor device being produced by a simpler process than the conventional one. Another objective of the present invention is to provide a production method of such a semiconductor device and a display device provided with such a semiconductor device.

### Solution to Problem

In the semiconductor device of the present invention including an insulating substrate and a first and a second thin film transistors supported by the insulating substrate, the first and the second thin film transistors have channel regions, respectively, the channel region of the first thin film transistor is formed in a first crystalline semiconductor layer having a first average grain diameter, the channel region of the second thin film transistor is formed in a second crystalline semiconductor layer having a second average grain diameter which is smaller than the first average grain diameter, and a thickness of the first crystalline semiconductor layer is larger than a thickness of the second crystalline semiconductor layer.

In one embodiment, a difference between the thickness of the first crystalline semiconductor layer and the thickness of the second crystalline semiconductor layer is not less than 5 nm and not more than 20 nm.

In one embodiment, the above-described semiconductor device is a semiconductor device including an active area and a peripheral area positioned around the active area, wherein the first thin film transistor is provided in the peripheral area, and the second thin film transistor is provided in the active area.

The display device of the present invention includes the above-described semiconductor device.

The production method of a semiconductor device of the present invention includes: a step a of preparing an insulating substrate in which an amorphous semiconductor layer is formed; a step b of adding a catalyst element for promoting the crystallization of the amorphous semiconductor to the entire of or a part of the amorphous semiconductor layer; a step c of thermally treating the amorphous semiconductor layer at temperatures not lower than 500° C. and not higher than 700° C., and crystallizing the amorphous semiconductor layer in the region to which the catalyst element is added by solid phase crystallization, thereby forming a crystalline semiconductor layer at least partially including a crystalline region; a step d of, after the step c, selectively forming a crystallization control layer by the same semiconductor material as that of the amorphous semiconductor layer only on a predetermined region of the crystalline semiconductor layer; a step e1 of melt crystallizing only part of the region in which the crystallization control layer is formed in the thickness direction of the crystalline semiconductor layer together with the crystallization control layer, thereby forming a first crystalline semiconductor layer; and a step e2 of melt crystallizing the region in which the crystallization control layer is not formed of the crystalline semiconductor layer, thereby forming a second crystalline semiconductor layer.

In one embodiment, the amorphous semiconductor layer is an amorphous silicon layer, and the crystallization control layer is an amorphous silicon layer or a microcrystalline silicon layer.

In one embodiment, the thickness of the crystallization control layer is not less than 5 nm and not more than 20 nm.

In one embodiment, the catalyst element includes at least one element of nickel, iron, cobalt, germanium, ruthenium, rhodium, palladium, osmium, iridium, platinum, copper, and gold.

In one embodiment, the steps e1 and e2 include a step of irradiating the crystallization control layer formed on the crystalline semiconductor layer and the crystalline semiconductor layer on which the crystallization control layer is not formed with a constant intensity laser beam.

In one embodiment, the step b includes a step of adding the catalyst element to the entire surface of the amorphous semiconductor layer.

### Advantageous Effects of Invention

According to the present invention, it is possible to provide a semiconductor device including crystalline semiconductor layers with different grain diameters on one and the same substrate, which can be produced by a simpler process than the conventional one. In addition, it is possible to provide a production method of such a semiconductor device, and a display device provided with such a semiconductor device.

### BRIEF DESCRIPTION OF DRAWINGS

In FIG. 1, (a) is a schematic sectional view of a semiconductor device 100A in one embodiment of the present invention, and (b) is a schematic plan view of the semiconductor device 100A.

In FIG. 2, (a) to (c) are sectional views illustrating the production process of the semiconductor device 100A.

In FIG. 3, (a) and (b) are plan views illustrating the production process of the semiconductor device 100A.

In FIG. 4, (a) to (d) are sectional views illustrating the production process of the semiconductor device 100A.

FIG. 5 is a graph showing a Vg-Id curve (a gate voltage-drain current curve) of a thin film transistor.

### DESCRIPTION OF EMBODIMENTS

With reference to the accompanying drawings, a semiconductor device in one embodiment of the present invention and the production method thereof will be described.

The semiconductor device in one embodiment of the present invention includes a substrate, and a first and a second TFTs supported by the insulating substrate. A channel region of the first TFT is formed in a first crystalline semiconductor layer having a first average grain diameter. A channel region of the second TFT is formed in a second crystalline semiconductor layer having a second average grain diameter which is smaller than the first average grain diameter. A thickness of the first crystalline semiconductor layer is larger than a thickness of the second crystalline semiconductor layer. In this specification, the term “an average grain diameter” of a semiconductor layer indicates an average of sizes of crystal grains included in the semiconductor layer when viewed from a normal direction of the semiconductor layer, and can be easily measured, for example, by EBSP (Electron backscatter diffraction patterns).

The semiconductor device in one embodiment of the present invention is, for example, a TFT substrate of a liquid crystal display device. Since the first TFT has the channel region which is formed in the semiconductor layer (e.g. a CG silicon layer) having relatively larger crystal grains, the electrical properties thereof such as mobility are superior to those of the second TFT. Since the semiconductor layer of the first TFT is relatively thicker than the semiconductor layer of the second TFT, the on-state current of the first TFT is larger than the on-state current of the second TFT. Accordingly, the first TFT is suitably used as a TFT for a peripheral circuit (a driving circuit) provided in a peripheral area of the TFT substrate for a full monolithic liquid crystal display device. The second TFT is suitably used as a TFT for a pixel provided in an active area (a display area of the liquid crystal display device). The semiconductor device in one embodiment of the present invention can be produced by a simpler process than the process described in Patent Document No. 2.

Hereinafter the semiconductor device in one embodiment of the present invention and the production method thereof will be described by exemplarily showing a TFT substrate used in a liquid crystal display device as the semiconductor device. The present invention is not limited to this, but the present invention can be applied to a TFT substrate used in an organic EL display device, for example.

With reference to FIG. 1 to FIG. 4, the configuration of a semiconductor device 100A in one embodiment of the present invention and the production method thereof will be described.

FIG. 1(a) and FIG. 1(b) show the configuration of the semiconductor device 100A in one embodiment of the present invention. FIG. 1(a) is a schematic sectional view of the semiconductor device 100A, and FIG. 1(b) is a schematic plan view of the semiconductor device 100A.

As shown in FIG. 1(a), the semiconductor device 100A includes a TFT (thin film transistor) 10A and a TFT 10B. The TFTs 10A and 10B are, for example, n-channel field-effect TFTs, respectively. In addition, as shown in FIG. 1(b), the semiconductor device 100A includes driving circuits 3 and 4, and a pixel electrode 5.

The TFT 10A is formed on a first insulating layer (an overcoat layer) 21 formed by an inorganic insulating layer such as a silicon dioxide layer which is formed on an insulating substrate (e.g. a glass substrate) 11. The TFT 10A includes a first crystalline semiconductor layer 30A formed on the first insulating layer 21, and a second insulating layer (a gate insulating layer) 22 formed by an inorganic insulating layer such as a silicon dioxide layer or a silicon nitride (SiNₓ) layer which is formed on the first crystalline semiconductor layer 30A. The first crystalline semiconductor layer 30A has a first semiconductor region (a channel region) 33a, a second semiconductor region (a source region) 34a, and a third semiconductor region (a drain region) 35a. In addition, the TFT 10A includes a first electrode (a gate electrode) 43a formed on the second insulating layer 22. A third insulating layer (an interlayer insulating layer) 23 is formed so as to cover the first electrode 43a. The TFT 10A has a second electrode (a source electrode) 44a1 formed on the third insulating layer 23 and electrically connected to the second semiconductor region 34a and a third electrode (a drain electrode) 44a2 formed on the third insulating layer 23 and electrically connected to the third semiconductor region 35a via contact holes which are formed through the second insulating layer 22 and the third insulating layer 23.

The TFT 10B includes a second crystalline semiconductor layer 30B formed on the first insulating layer 21, and a second insulating layer (a gate insulating layer) 22 formed by an inorganic insulating layer such as a silicon dioxide layer or a silicon nitride layer which is formed on the second crystalline semiconductor layer 30B. The second crystalline semiconductor layer 30B has a first semiconductor region (a channel region) 33b, a second semiconductor region (a source region) 34b, and a third semiconductor region (a drain region) 35b. In addition, the TFT 10B includes a first electrode (a gate electrode) 43b formed on the second insulating layer 22. A third insulating layer (an interlayer insulating layer) 23 is formed so as to cover the first electrode 43b. The TFT 10B has a second electrode (a source electrode) 44b1 formed on the third insulating layer 23 and electrically connected to the second semiconductor region 34b and a third electrode (a drain electrode) 44b2 formed on the third insulating layer 23 and electrically connected to the third semiconductor region 35b via contact holes which are formed through the second insulating layer 22 and the third insulating layer 23.

Herein as for the first crystalline semiconductor layer 30A, the average grain diameter and the thickness thereof are larger than those of the second crystalline semiconductor layer 30B. The first crystalline semiconductor layer 30A and the second crystalline semiconductor layer 30B are, for example, crystalline silicon layers. The first crystalline semiconductor layer 30A is, for example, a CG silicon layer, and the second crystalline semiconductor layer 30B is, for example, a polycrystalline silicon layer (an LTPS layer). At this time, the average grain diameter of the first crystalline semiconductor layer 30A is about 4 μm, for example, and the average grain diameter of the second crystalline semiconductor layer 30B is 0.3 μm (300 nm). In addition, the thickness of the first crystalline semiconductor layer 30A is larger than the thickness of the second crystalline semiconductor layer 30B, and the difference between them is preferably not less than 5 nm and not more than 20 nm. For example, the thickness of the first crystalline semiconductor layer 30A is 60 nm, and the thickness of the second crystalline semiconductor layer 30B is 50 nm, so that the difference between them is 10 nm.

The whole of the active area of the TFT 10A (including the channel region, the source region, and the drain region) is not necessarily formed in the first crystalline semiconductor layer 30A, but it is sufficient that at least the channel region of the TFT 10A be formed in the first crystalline semiconductor layer 30A. For example, the source and drain regions of the TFT 10A may be amorphous silicon layers for gettering a catalyst element.

Since the first crystalline semiconductor layer 30A and the second crystalline semiconductor layer 30B have mutually different average grain diameters and thicknesses, the TFT 10A and the TFT 10B have mutually different electrical properties (e.g. mobility). Accordingly, when TFTs having different electrical properties and sizes are to be formed on one and the same substrate, it is sufficient to form crystalline semiconductor layers suitable for the required electrical properties.

Specifically, since the average grain diameter and the thickness of the first crystalline semiconductor layer 30A are larger than those of the second crystalline semiconductor layer 30B, the TFT 10A including the first crystalline semiconductor layer 30A has a higher degree of mobility and a larger on-state current as its properties. Since the average grain diameter and the thickness of the second crystalline semiconductor layer 30B are smaller than those of the first crystalline semiconductor layer 30A, the TFT 10B including the second crystalline semiconductor layer 30B has less variation in Vth (threshold value) as its properties. The average grain diameter of the first crystalline semiconductor layer 30A included in the TFT 10A is preferably 2 μm or more in order to attain a sufficient degree of mobility, and equal to or less than ⅕ of the channel length (e.g. 4 μm) in order that the variation in Vth is not so large. The average grain diameter of the second crystalline semiconductor layer 30B included in the TFT 10B is preferably 0.1 μM or more in order to attain a sufficient degree of mobility, and equal to or less than 1/10 of the channel length (e.g. 0.4 μm) in order to sufficiently suppress the variation in Vth.

In order to take advantages of respective properties of the TFT 10A and the TFT 10B, for example in a full monolithic liquid crystal display device, the TFT 10A is preferably used as a TFT of a peripheral circuit in a peripheral area 2 (an area other than an active area 1) of the TFT substrate as shown in FIG. 1(b), and the TFT 10B is preferably used as a TFT for a pixel in the active area 1.

For example, the channel region 33a of the TFT 10A has an area of 20 μm×20 μm, and the channel region 33b of the TFT 10B has an area of 4 μm×4 μm. The channel length of the TFT 10A is 20 μm, and the average grain diameter of the first crystalline semiconductor layer 30A is about 4 μm. Accordingly, the mean value of the number of grain boundaries intersecting the channel direction of the TFT 10A is 4, so that the variation in Vth is not large. On the other hand, the channel length of the TFT 10B is 4 μm, and the average grain diameter of the second crystalline semiconductor layer 30B is about 0.3 μm. Accordingly, the mean value of the number of grain boundaries intersecting the channel direction of the TFT 10B exceeds 10, so that the variation in Vth is less than the TFT 10A.

A display device (e.g. a liquid crystal display device) including the semiconductor device 100A is provided with the TFT 10B having a crystalline semiconductor layer with less variation in Vth in the active area 1, and provided with the TFT 10A having a crystalline semiconductor layer with a higher degree of mobility and a larger on-state current in the peripheral area 2, so that it is possible to realize stable display with less variations in display brightness and colors.

The production method of a semiconductor device in one embodiment of the present invention includes a step a of preparing an insulating substrate on which an amorphous semiconductor layer is formed, a step b of adding a catalyst element for promoting crystallization of the amorphous semiconductor layer to the entire of or a part of the amorphous semiconductor layer, a step c of thermally treating the amorphous semiconductor layer at temperatures not lower than 500° C. and not higher than 700° C., and crystallizing the amorphous semiconductor layer in the region to which the catalyst element is added by solid phase crystallization, thereby forming a crystalline semiconductor layer at least partially including a crystalline area, a step d of, after the step c, selectively forming a crystallization control layer only on a predetermined region of the crystalline semiconductor layer by using one and the same semiconductor material as that of the amorphous semiconductor layer, a step e1 of melt crystallizing only part of the region in which the crystallization control layer is formed in the thickness direction of the crystalline semiconductor layer together with the crystallization control layer, thereby forming a first crystalline semiconductor layer, and a step e2 of melt crystallizing a region in which the crystallization control layer is not formed of the crystalline semiconductor layer, thereby forming a second crystalline semiconductor layer. According to this method, the above-described semiconductor device 100A can be produced. According to the method, the semiconductor device can be produced through a simple process without requiring the formation and removal of the upper layer as in the production method described in Patent Document No. 2.

The amorphous semiconductor layer is an amorphous silicon layer, for example. The crystallization control layer is an amorphous silicon layer or a microcrystalline silicon layer, for example. The microcrystalline silicon layer can be formed by high-density plasma CVD. The steps e1 and e2 may include a step of irradiating the crystallization control layer formed on the crystalline semiconductor layer and the crystalline semiconductor layer in a region in which the crystallization control layer is not formed with a constant intensity laser beam. In other words, the optimum laser beam intensity for forming the first crystalline semiconductor layer and the second crystalline semiconductor layer can be regulated by the provision of the crystallization control layer, so that the upper layer described in Patent Document No. 2 is not required, and the crystallization control layer eventually becomes part of the first crystalline semiconductor layer, so that a step of removing the crystallization control layer is not required.

In addition, if the step b is a step of adding the catalyst element to the entire surface of the amorphous semiconductor layer, a mask for selectively adding the catalyst element only to the predetermined region is not required.

Next, with reference to FIG. 2 to FIG. 4, one embodiment of the production method of the semiconductor device 100A will be described in detail.

As shown in FIG. 2(a), on an insulating substrate (e.g. a glass substrate) 11, a first insulating layer containing silicon dioxide (a base coat layer) 21 is formed up to 100 nm in thickness by CVD (Chemical Vapor Deposition) or other technique by using TEOS (Tetra Etoxy Silane) as a material gas. The first insulating layer 21 may contain, other than silicon dioxide, silicon nitride, silicon oxynitride (SiNO), or the like, and may have a single layer structure or a layered structure.

Next, as an amorphous semiconductor layer, a silicon layer having an amorphous structure (hereinafter referred to as an “amorphous silicon layer”) 31 is formed up to a thickness of not less than 20 nm and not more than 150 nm (preferably not less than 30 nm and not more than 80 nm) by a known method such as plasma CVD or sputtering. In this embodiment, the amorphous silicon layer (sometimes referred to as an amorphous semiconductor layer) 31 is formed up to 50 nm in thickness by LPCVD (Low Pressure CVD) by using silane (SiH₄) as a material gas. Herein in the case where the thickness of the amorphous silicon layer 31 is less than 20 nm, the thickness of the layer is widely varied in fabrication, so that a uniform amorphous silicon layer cannot be obtained in some cases. In the case where the thickness is more than 150 nm, in a second crystallization step which will be described later, it is necessary to increase the energy of laser for irradiation, so that a good crystalline semiconductor layer cannot be obtained over the entire surface thereof in some cases. In addition, in the amorphous silicon layer 31, a gettering region having an effect of gathering a catalyst element which will be described later (the gettering effect) may be formed as shown in Patent Document No. 3.

Next, as shown in FIG. 2(b), a catalyst element layer 41 is formed over an entire surface of the amorphous silicon layer 31 by resistance heating with a catalyst element which promotes the crystallization (herein nickel). In the case where the catalyst element is added to part of the amorphous silicon layer 31, a mask is provided on the amorphous silicon layer 31 by a photo resist or the like, and the catalyst element is added only to a desired region of the amorphous silicon layer 31. After the addition of the catalyst element, the mask is removed. Thus, the number of process steps can be smaller in the case where the catalyst element is added to the entire surface of the amorphous silicon layer 31.

In this embodiment, the concentration of the catalyst element at the surface of the amorphous silicon layer 31 is about 5×10¹⁰ atoms/cm² in a region in a depth direction of not less than 5 nm and not more than 10 nm from the surface of the amorphous silicon layer 31 by Total Reflection X-ray Fluorescence (TRXRF). As the catalyst element, other than nickel (Ni), it is preferred to use one or a plurality of elements selected from a group consisting of iron (Fe), cobalt (Co), germanium (Ge), lead (Pb), palladium (Pd), copper (Cu), ruthenium (Ru), rhodium (Rh), osmium (Os), iridium (Ir), platinum (Pt), and gold (Au). This embodiment adopts the method in which the catalyst element layer 41 is formed by resistance heating, but alternatively may adopt a method in which a solution including the catalyst element is applied by spin coating, or a method in which a layer including a catalyst element is formed or doped on the amorphous silicon layer 31 by sputtering or other techniques. The concentration of the catalyst element at the surface of the amorphous semiconductor layer is preferably not less than 1×10¹⁰ atoms/cm² and not more than 1×10¹² atoms/cm². Accordingly, the semiconductor device can be efficiently produced, and moreover the properties of the semiconductor layer can be efficiently improved. If the concentration of the catalyst element at the surface of the amorphous semiconductor layer is less than 1×10¹⁰ atoms/cm², the effect of the catalyst element is low, and the period of time required for the crystallization of the amorphous semiconductor layer is elongated, which are not preferable in view of the production process. On the other hand, if the concentration of the catalyst element at the surface of the amorphous semiconductor layer exceeds 1×10¹² atoms/cm², the density of crystal grains caused by the catalyst element increases, but the average grain diameter caused by the catalyst element decreases, so that the desired properties cannot sometimes be obtained.

Next, as a first crystallization step of crystallizing the amorphous silicon layer 31, in this embodiment, heat treatment is performed at 600° C. for one hour under an inert gas atmosphere (e.g. under an atmosphere of nitrogen). As the heat treatment, preferably, annealing is performed at temperatures not lower than 500° C. and not higher than 700° C. By performing the heat treatment of the amorphous silicon layer in the above-mentioned temperature range, it is possible to obtain such an advantage that the first crystallization step is performed while the improvement in the efficiency of the production process and the improvement in the properties of the semiconductor layer are both attained. If the heat treatment is performed at temperatures lower than 500° C., the speed of the solid phase crystal growth decreases. On the other hand, if the temperatures exceed 700° C., in addition to the crystal grains which are grown by solid-phase crystallization by the catalyst element, crystal grains having smaller grain diameters, for example, less than 0.2 μm which are not caused by the catalyst element are grown, so that the desired properties cannot sometimes be obtained.

By the first crystallization step, solid phase crystal growth of the amorphous silicon layer 31 is performed, thereby obtaining a crystalline silicon layer 31′. At this time, the average grain diameter of the crystalline silicon layer 31′ is not less than 3.0 μm and not more than 10 μm. Herein, for example, it is about 4 μm. Due to the heat treatment, as for the region in which the catalyst element layer 41 is formed in the amorphous silicon layer 31, nickel added to the surface of the amorphous silicon layer 31 is dispersed in the amorphous silicon layer 31. In addition, silicidation occurs and the solid phase crystallization of the amorphous silicon layer 31 progresses by using the silicide as seeds. As a result, the amorphous silicon layer 31 in the region in which the catalyst element layer 41 is formed is crystallized, thereby forming the crystalline silicon layer 31′. Herein the crystallization is performed by heat annealing using a furnace. Alternatively, the crystallization may be performed with RTA (Rapid Thermal Annealing) apparatus using a lamp or the like as a heat source.

Next, as shown in FIG. 2(c), on the surface of the crystalline silicon layer 31′, an amorphous silicon layer 51 is formed. For example, the amorphous silicon layer 51 of 10 nm in thickness is formed by LPCVD by using silane (SiH₄) as a material gas. The amorphous silicon layer 51 may be formed by any known method such as atmospheric pressure CVD or sputtering, other than LPCVD.

The thickness of the amorphous silicon layer 51 is preferably not less than 5 nm and not more than 20 nm. The amorphous silicon layer 51 will function as a crystallization control layer 51′ which will be described later in the succeeding step. If the thickness of the amorphous silicon layer 51 is less than 5 nm, the presence or absence of the crystallization control layer 51′ has no difference in the case where the energy applied in a second crystallization step which will be described later is high. That is, all of the semiconductor layers including the region covered with the crystallization control layer 51′ on the substrate are melted by the applied energy. As a result, the obtained semiconductor layer is a semiconductor layer having a smaller average grain diameter. In the case where the energy applied in the second crystallization step is low, a semiconductor layer having desired average grain diameter and crystallinity cannot be obtained in some cases.

On the other hand, if the thickness of the amorphous silicon layer 51 is more than 20 nm, the optimum applied energy for improving the crystallinity of the crystalline silicon layer 31′ covered with the crystallization control layer 51′ in the second crystallization step is different from the optimum applied energy for obtaining a second crystalline semiconductor layer 30B which will be described later, which is not preferable in view of the production process. As described later, the final difference in thickness between the first crystalline semiconductor layer 30A and the second crystalline semiconductor layer 30B is determined depending on the thickness of the amorphous silicon layer 51.

Next, as shown in FIG. 3(a), the amorphous silicon layer 51 formed on the crystalline silicon layer 31′ is patterned by photolithography or the like, thereby forming a crystallization control layer 51′. The crystallization control layer 51′ is provided on a region in which the average grain diameter is desired to be maintained of the crystalline silicon layer 31′ formed in the first crystallization step. In this case, the crystallization control layer 51′ is preferably an amorphous silicon layer or a microcrystalline silicon layer. If the crystallization control layer 51′ is formed by using the amorphous silicon layer or the microcrystalline silicon layer, a layer having uniform thickness can be obtained even in a large-size substrate.

Next, as shown in FIG. 3(b), in the second crystallization step, pulse oscillation type excimer laser beam 61 (e.g. pulse oscillation type XeCl excimer laser) of not less than 126 nm and not more than 370 nm in wavelength (e.g. 308 nm in wavelength) and of 30 ns in pulse width, for example, is linearly shaped into 125 mm×0.4 mm over an entire surface of the substrate, and the scanning is performed by a step width of 20 μm/pulse in a short-axis direction (the direction indicated by an arrow in FIG. 3(b)) of the pulse oscillation type excimer laser beam 61 on the insulating substrate 11.

If the pulse oscillation type XeCl excimer laser is used, the semiconductor layer can be irradiated with a long laser beam while performing the step scanning, so that an advantage that large area can be easily processed for a short period of time can be attained. If a laser beam of not less than 126 nm and not more than 370 nm in wavelength is used, the selectivity of melting in the depth direction is superior depending on the presence or absence of the crystallization control layer 51′. In other words, the thickness of the semiconductor layer is increased by the thickness of the crystallization control layer 51′, so that the region in which the crystallization control layer 51′ is formed in the vicinity of the interface between the crystalline silicon layer 31′ and the first insulating layer 21 is not melted, and the region of the crystalline silicon layer 31′ in which the crystallization control layer 51′ is not formed can be melted up to the interface with the first insulating layer 21.

Part of the crystalline silicon layer 31′ is not melted and left, so that the crystal grains of the remaining crystalline silicon layer 31′ function as the seed, and the crystallization (recrystallization) progresses, thereby eventually forming a first crystalline semiconductor layer 30A together with the melted crystallization control layer 51′. The average grain diameter of the first crystalline semiconductor layer 30A is substantially equal to or more than the average grain diameter of the crystalline silicon layer 31′, so that the crystallinity is improved. On the other hand, the crystalline silicon layer 31′ which is not covered with the crystallization control layer 51′ is completely melted, and a second crystalline semiconductor layer 30B constituted by a polycrystalline silicon layer can be obtained by melt crystallization.

As for the output of the pulse oscillation type excimer laser beam 61, the energy density for irradiating the surface of the crystalline silicon layer 31′ is, for example, not less than 250 mJ/cm² and not more than 450 mJ/cm² (herein e.g. 350 mJ/cm²). It is preferred that the conditions of irradiation energy in the second crystallization step are in the range of the conditions capable of improving the crystallinity of the crystalline silicon layer 31′ on which the crystallization control layer 51′ is formed, and the conditions which do not change the average grain diameter of the crystalline silicon layer 31′. For example, the conditions are such that the region of about 5 nm in thickness from the interface between the crystalline silicon layer 31′ and the first insulating layer 21 in the region covered with the crystallization control layer 51′ is not melted.

In addition, by irradiating the crystalline silicon layer 31′ with the linearly-shaped laser beam over the entire surface of the substrate while performing the step scanning in the short-axis direction of the laser beam, the crystallinity can be improved while the grain diameter of the crystalline silicon layer 31′ covered with the crystallization control layer 51′ is maintained. In addition, the crystalline silicon layer 31′ which is not covered with the crystallization control layer 51′ can be efficiently and simply crystallized.

The term “a linearly-shaped laser beam” means an oblong (rectangular) or oval laser beam, and the aspect ratio thereof is preferably 2 or more. More preferably, the aspect ratio is in the range of 10 to 10000. If the laser beam is linearly shaped, it is possible to ensure the energy density to the extent of sufficiently annealing the object to be irradiated. Alternatively, if sufficiently annealing can be performed for the object to be irradiated, the shape of the beam is not limited to be linear. The term “the short-axis direction of the laser beam” indicates a direction substantially perpendicular to the substantially linear direction of the laser beam. The term “the step scanning” is a scanning method in which the laser beam is moved with a certain step width (a distance by which the irradiation position is moved between one beam shot and the next beam shot) after every beam shot. The step width is not specifically limited if the annealing can be performed to the object to be irradiated without any interval, and can be appropriately determined.

As described above, by the irradiation with the pulse oscillation type excimer laser beam 61, the crystalline silicon layer 31′ in the region in which the crystallization control layer 51′ is formed is made into the first crystalline semiconductor layer 30A together with the crystallization control layer 51′. The crystallization control layer 51′ is crystallized unitedly with the crystalline silicon layer 31′, so that the thickness of the first crystalline silicon layer 30A is 60 nm. In addition, the average grain diameter of the first crystalline semiconductor layer 30A is not affected by the second crystallization step, and is not varied from about 4 μm.

On the other hand, the crystalline silicon layer 31′ in the region in which the crystallization control layer 51′ is not formed is crystallized after being completely melted by the irradiation with the pulse oscillation type excimer laser beam 61, thereby forming a second crystalline semiconductor layer 30B. The thickness of the second crystalline semiconductor layer 30B is maintained to be 50 nm. The average grain diameter of the second crystalline semiconductor layer 30B is about 0.3 μm, for example.

Next, with reference to FIG. 4, the fabrication method of a TFT 10A and a TFT 10B which utilize the first crystalline semiconductor layer 30A and the second crystalline semiconductor layer 30B formed as described above as channel regions 33a and 33b, respectively, will be described.

As shown in FIG. 4(a), a second insulating layer 22 having an oxide film such as silicon dioxide, for example, was formed up to not less than 30 nm and not more than 150 nm in thickness (herein about 100 nm) by CVD or the like using TEOS as a material gas so as to cover the first crystalline semiconductor layer 30A and the second crystalline semiconductor layer 30B. The second insulating layer (a gate insulating layer) 22 may have SiNₓ, SiNO, or the like, other than SiO₂. The second insulating layer 22 may be a single layer or may have a layered structure.

Next, after a metal layer (herein an aluminum layer) of about 300 nm in thickness is formed on the second insulating layer 22 by sputtering or the like as shown in FIG. 4(b), the metal layer 42 is patterned into a predetermined shape by photolithography or the like, thereby forming gate electrodes 43a and 43b as shown in FIG. 4(c). The materials of the metal layer 42 (the gate electrodes 43a and 43b) may include, other than aluminum (Al), high melting point metals such as tungsten (W), molybdenum (Mo), tantalum (Ta), and titanium (Ti), nitrides of the corresponding high melting point metals, or the like. The gate electrodes 43a and 43b may have a single layer structure having the above-described material or a layered structure having a plurality of materials.

Next, after impurity ions, e.g. phosphorus ions are introduced (doped) into the first crystalline semiconductor layer 30A and the second crystalline semiconductor layer 30B with the respective gate electrodes 43a and 43b used as masks, activation annealing is performed in an electric furnace, thereby forming source regions 34a and 34b and drain regions 35a and 35b in the first crystalline semiconductor layer 30A and the second crystalline semiconductor layer 30B in the regions which are not masked by the respective gate electrodes 43a and 43b. At this time, since the thickness of the first crystalline semiconductor layer 30A is larger, the sheet resistance value of the region into which the phosphorus ions are doped is lower than that of the second crystalline semiconductor layer 30B. Alternatively, the impurity ions may be boron ions, other than the phosphorus ions.

Next, the regions of the first crystalline semiconductor layer 30A and the second crystalline semiconductor layer 30B masked by the respective gate electrodes 43a and 43b are channel regions 33a and 33b. As described above, the first crystalline semiconductor layer 30A and second crystalline semiconductor layer 30B have the source regions 34a and 34b and the drain regions 35a and 35b which are opposed with the channel regions 33a and 33b interposed therebetween.

Next, as shown in FIG. 4(d), an insulating layer having an oxide film such as silicon dioxide, for example, is formed up to the thickness not less than 400 nm and not more than 1500 nm, for example, by atmospheric pressure CVD or the like over an entire surface of the insulating substrate 11 so as to cover the gate electrodes 43a and 43b, thereby forming an interlayer insulating layer 23. The thickness of the interlayer insulating layer 23 is 500 nm, for example. It is understood that the interlayer insulating layer 23 may be a single layer or may have a layered structure.

Next, as shown in FIG. 1(a), contact holes are formed through the second insulating layer 22 and the interlayer insulating film 23 on the source regions 34a and 34b and the drain regions 35a and 35b. A film of an electrode material is formed by sputtering or the like over an entire surface of the insulating substrate 11, and then patterned, thereby forming source electrodes 44a1 and 44b1, and drain electrodes 44a2 and 44b2, respectively. With such a configuration, ohmic contact is realized respectively between the source electrodes 44a1, 44b1 and the drain electrodes 44a2, 44b2, and the source regions 34a, 34b and the drain regions 35a, 35b, thereby obtaining the TFT 10A and the TFT 10B.

As for the TFT 10A which was experimentally produced by the above-described method, the degree of carrier mobility was measured, so as to obtain such a high property as 350 cm²/V·s. However, the variation in Vth of fifty TFTs 10A was 0.15 V. On the other hand, as for the TFT 10B, the degree of carrier mobility was measured, so as to obtain 180 cm²/V·s, but the variation in Vth of fifth TFTs 10B was 0.05 V, which was smaller than the measured result (0.15 V) of the TFT 10A.

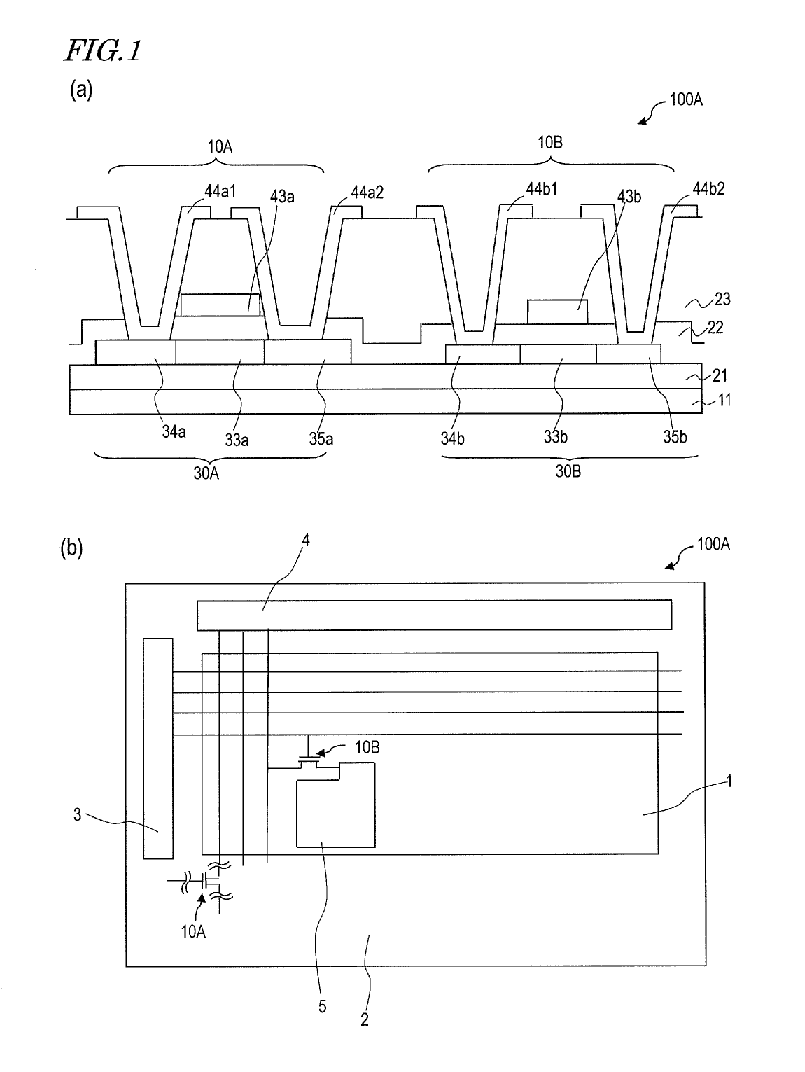

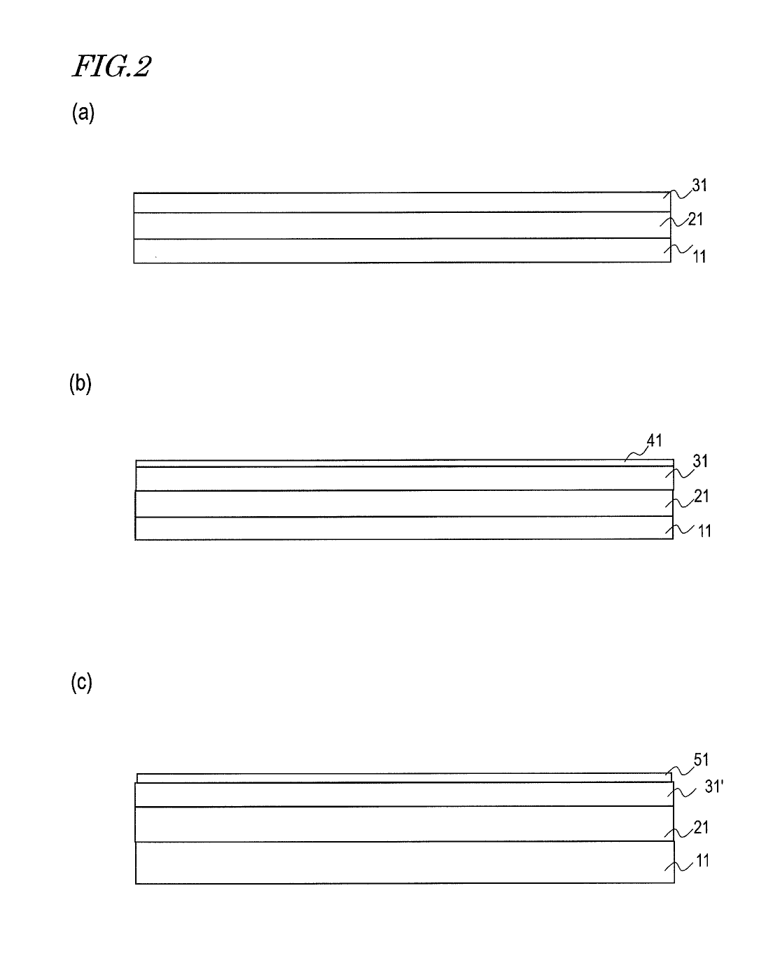

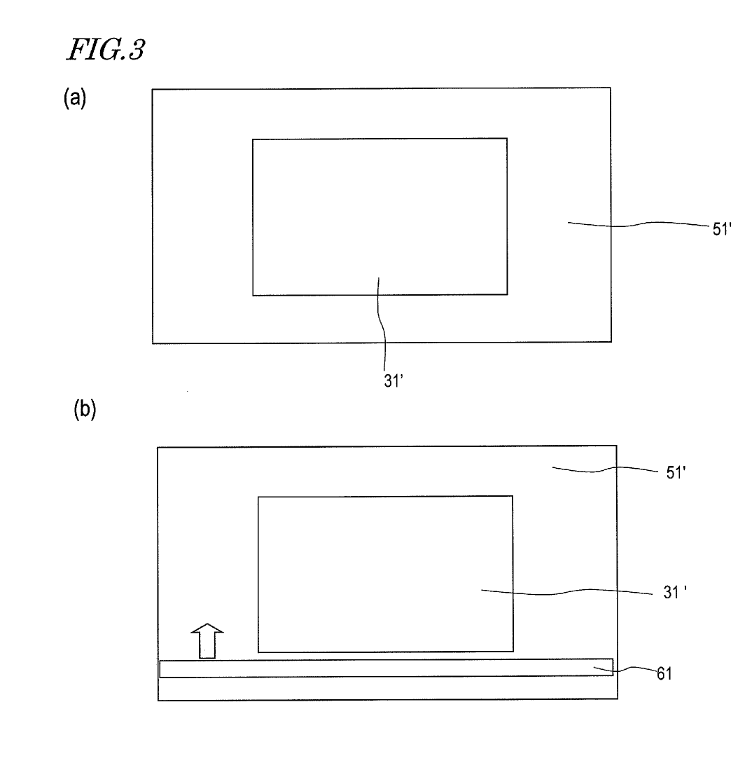

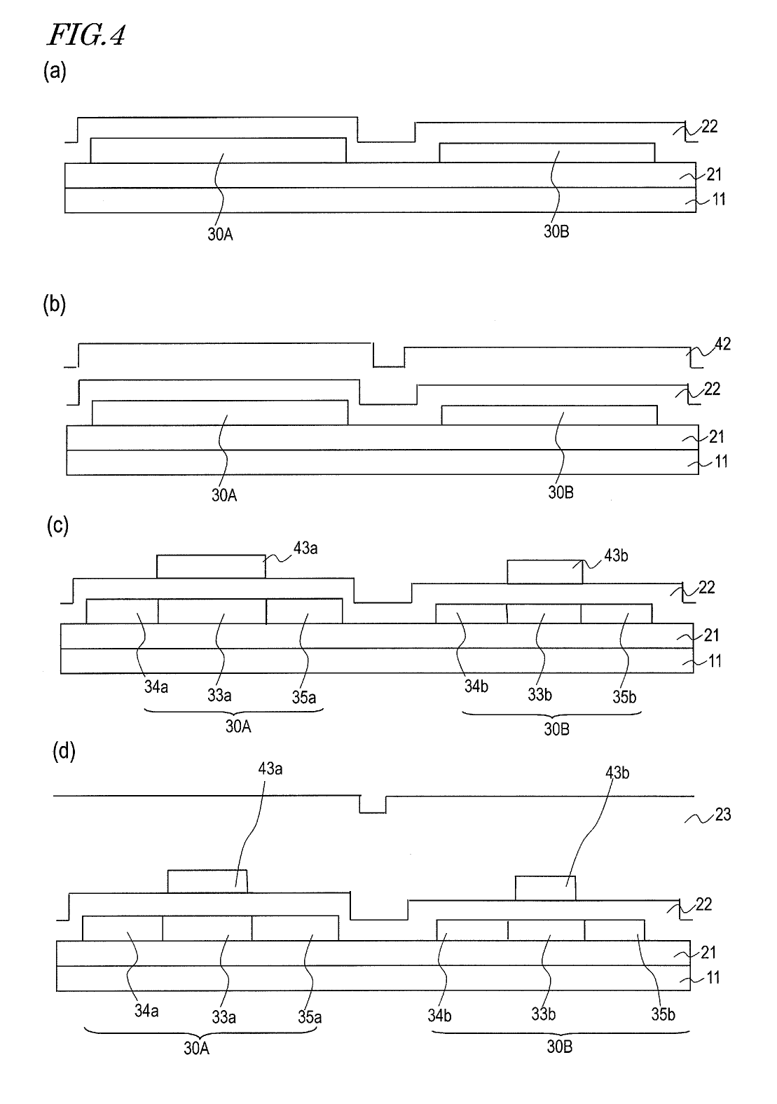

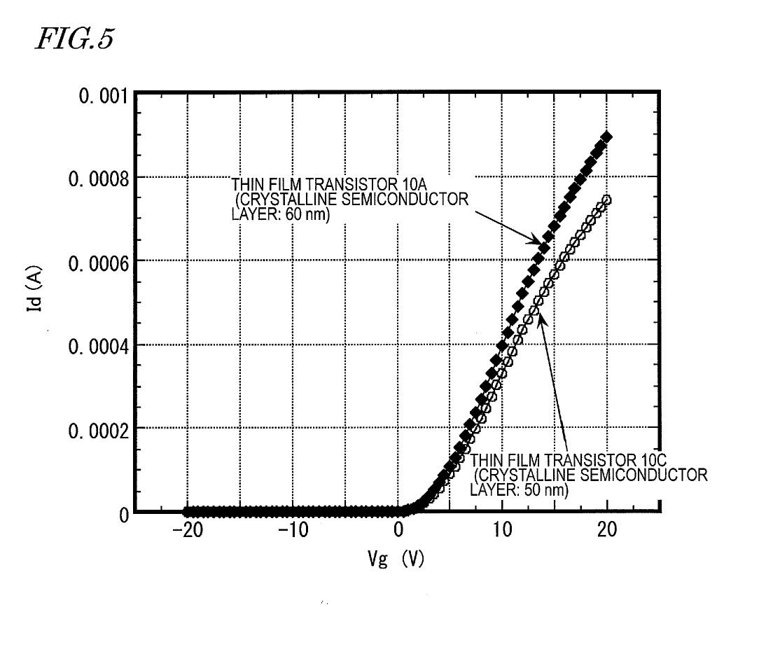

As shown in FIG. 5, on-state current characteristics of a TFT 10C having a crystalline semiconductor layer (thickness: 50 nm) with the same average grain diameter and crystallinity as those of the first crystalline semiconductor layer 30A (thickness: 60 nm) included in the TFT 10A and with a thickness only which was different from that of the first crystalline semiconductor layer were measured and compared. The on-state current of the TFT 10A having the first crystalline semiconductor layer 30A of 60 nm in thickness was larger. In other words, it is found that, even in the case where the average grain diameters and the crystallinities are the same, if the thicknesses of the crystalline semiconductor layers are different, the electrical properties of the TFTs are also different, and the on-state current of the TFT having the thicker semiconductor layer is larger.

As described above, by fabricating TFTs having different electrical properties on one and the same substrate, it is possible to obtain a semiconductor device in which the most suitable TFTs can be fabricated for the respective TFTs on one and the same substrate. Moreover, a display device provided with such a semiconductor device (for example, a liquid crystal display device) has less variation in brightness and colors, so that stable display can be realized.

### INDUSTRIAL APPLICABILITY

The applicable range of the present invention is extremely wide, and the present invention can be applied to a semiconductor device provided with a TFT, or electronic equipment in any field having such a semiconductor. For example, a circuit or a pixel portion formed by embodying the present invention can be used in an active matrix liquid crystal display device or an organic EL display device. Such a display device can be utilized, for example, as a display screen of a mobile phone or a portable game machine, a monitor of a digital camera, and the like. Accordingly, the present invention can be applied to any electronic equipment in which a liquid crystal display device or an organic EL display device is incorporated.

### REFERENCE SIGNS LIST

1 Matrix area
2 Peripheral area
3, 4 Driving circuits
5 Pixel electrode
10A TFT
10B TFT
10B Insulating substrate
21, 22, 23 Insulating layers
30A First crystalline semiconductor layer
30B Second crystalline semiconductor layer
33a, 33b Channel regions
34a, 34b Source regions
35a, 35b Drain regions
43a, 43b Gate electrodes
44a1, 44b1 Source electrodes
44a2, 44b2 Drain electrodes
100A Semiconductor device

1. A semiconductor device comprising an insulating substrate and a first and a second thin film transistors supported by the insulating substrate, wherein
the first and the second thin film transistors have channel regions, respectively, the channel region of the first thin film transistor is formed in a first crystalline semiconductor layer having a first average grain diameter,
the channel region of the second thin film transistor is formed in a second crystalline semiconductor layer having a second average grain diameter which is smaller than the first average grain diameter, and
a thickness of the first crystalline semiconductor layer is larger than a thickness of the second crystalline semiconductor layer.

2. The semiconductor device of claim 1, wherein a difference between the thickness of the first crystalline semiconductor layer and the thickness of the second crystalline semiconductor layer is not less than 5 nm and not more than 20 nm.

3. The semiconductor device of claim 1 comprising an active area and a peripheral area positioned around the active area, wherein
the first thin film transistor is provided in the peripheral area, and
the second thin film transistor is provided in the active area.

4. A display device comprising a semiconductor device of claim 1.

5. A production method of a semiconductor device comprising:
a step a of preparing an insulating substrate in which an amorphous semiconductor layer is formed;
a step b of adding a catalyst element for promoting the crystallization of the amorphous semiconductor to the entire of or a part of the amorphous semiconductor layer;
a step c of thermally treating the amorphous semiconductor layer at temperatures not lower than 500° C. and not higher than 700° C., and crystallizing the amorphous semiconductor layer in the region to which the catalyst element is added by solid phase crystallization, thereby forming a crystalline semiconductor layer at least partially including a crystalline region;
a step d of, after the step c, selectively forming a crystallization control layer by the same semiconductor material as that of the amorphous semiconductor layer only on a predetermined region of the crystalline semiconductor layer;
a step e1 of melt crystallizing only part of the region in which the crystallization control layer is formed in the thickness direction of the crystalline semiconductor layer together with the crystallization control layer, thereby forming a first crystalline semiconductor layer; and
a step e2 of melt crystallizing the region in which the crystallization control layer is not formed of the crystalline semiconductor layer, thereby forming a second crystalline semiconductor layer.

6. The production method of a semiconductor device of claim 5, wherein the amorphous semiconductor layer is an amorphous silicon layer, and the crystallization control layer is an amorphous silicon layer or a microcrystalline silicon layer.

7. The production method of a semiconductor layer of claim 5, wherein the thickness of the crystallization control layer is not less than 5 nm and not more than 20 nm.

8. The production method of a semiconductor layer of claim 5, wherein the catalyst element includes at least one element of nickel, iron, cobalt, germanium, ruthenium, rhodium, palladium, osmium, iridium, platinum, copper, and gold.

9. The production method of a semiconductor device of claim 5, wherein the steps e1 and e2 include a step of irradiating the crystallization control layer formed on the crystalline semiconductor layer and the crystalline semiconductor layer on which the crystallization control layer is not formed with a constant intensity laser beam.

10. The production method of a semiconductor device of claim 5, wherein the step b includes a step of adding the catalyst element to the entire surface of the amorphous semiconductor layer.
